(19) United States
(12) Patent Application Publication
(10) Pub. No.: US 2012/0171865 A1
(43) Pub. Date: Jul. 5, 2012

(54) METHOD FOR FABRICATING FINE PATTERNS

(75) Inventor: Min Ae YOO, Icheon-si (KR)

(73) Assignee: HYNIX SEMICONDUCTOR INC., Icheon-si (KR)

(21) Appl. No.: 13/243,702

(22) Filed: Sep. 23, 2011

(30) Foreign Application Priority Data
Dec. 29, 2010 (KR) 10-2010-0137926

(51) Int. Cl. H01L 21/311; G03F 7/20

(52) U.S. Cl. 438/694; 430/322; 257/E21.257

(57) ABSTRACT

A method for fabricating fine patterns includes forming a first photomask including first line patterns and first assist features and forming a second photomask including second line patterns extending to a portion corresponding to the first assist features in a direction perpendicular to the first line patterns. A first resist layer may be exposed through a first exposure process by using the first photomask, and a first resist pattern formed to open regions following the shape of the first line patterns. The first resist pattern may be frozen and a second resist layer may be formed to fill the opened regions of the first resist pattern. The second resist layer may be exposed through a second exposure process by using the second photomask, and a second resist pattern formed to open regions corresponding to the intersections between the first and second line patterns with the first resist pattern.

### CROSS-REFERENCES TO RELATED APPLICATIONS

The present application claims priority under 35 U.S.C 119(a) to Korean Application No. 10-2010-0137926, filed on Dec. 29, 2010 in the Korean intellectual property Office, and which is incorporated herein by reference in its entirety.

### BACKGROUND

Exemplary embodiments of the present invention relate to a method for fabricating a semiconductor device, and more particularly, to a method for fabricating fine patterns by using a lithography-freezing-lithography-etching (LFLE) process.

As the design rule of semiconductor devices shrinks, the size of patterns forming a device has been rapidly reduced. As the patterns required for forming a DRAM memory device or phase change random access memory are reduced in size, pattern fabrication techniques using a double lithography or double patterning process have been adopted as a method for implementing a fine pattern on a wafer at a size equal to or less than resolution that may be realized during a lithography process. A first resist pattern is formed, and a second resist pattern is formed over the resultant structure. Then, a fine pattern may be implemented according to a result obtained by combining the first and second resist patterns. Among the double patterning techniques, a lithography-lithography-etching (LLE) or LFLE process, in which a first resist pattern is exposed by a first exposure process, a second resist pattern is exposed by a second exposure process, and an etching process is performed, may simplify the entire process, because the etching process is performed at one step. Therefore, it is expected that the LLE or LEFE process will be effective in fabricating a fine pattern.

### SUMMARY

An embodiment of the present invention relates to a method that can suppress a previously formed first resist pattern from being deformed or developed during a process of forming a second resist pattern when fabricating fine patterns by using an LFLE process.

In one embodiment, a method for fabricating fine patterns includes forming a first photomask including first line patterns and first assist features positioned outside the first line patterns and having a line shape to extend in a direction perpendicular to the first line patterns. A second photomask may be formed that includes second line patterns extending to a portion corresponding to the first assist features in a direction perpendicular to the first line patterns. A first resist layer may be exposed through a first exposure process by using the first photomask, and a first resist pattern may be formed to open regions following the shape of the first line patterns. The first resist pattern may be frozen. A second resist layer may be formed to fill the opened regions of the first resist pattern and the second resist layer may be exposed through a second exposure process by using the second photomask, and a second resist pattern may be formed to open regions corresponding to the intersections between the first and second line patterns with the first resist pattern.

In another embodiment, a method for fabricating fine patterns includes defining a cell region in which cell patterns are to be formed and an edge region outside the cell region on a wafer. A first photomask may be formed including first line patterns extending in an X-axis direction from the cell region to the edge region and first assist features may be positioned in the edge region outside the first line patterns and having a line shape in a Y-axis direction perpendicular to the X-axis direction. A second photomask may be formed including second line patterns extending in the Y-axis direction from the cell region to the edge region. The first resist layer may be exposed through a first exposure process by using the first photomask, and a first resist pattern may be formed to open regions following the shape of the first line patterns. The first resist pattern may then be frozen. A second resist layer may be formed to fill the opened regions of the first resist pattern, and the second resist layer may be exposed through a second exposure process by using the second photomask. A second resist pattern may be formed that opens regions corresponding to the intersections between the first and second line patterns as the cell patterns with the first resist pattern.

In another embodiment, a method for fabricating fine patterns includes obtaining a photomask layout including first line patterns, first assist features formed outside the first line patterns and having a line shape in a direction perpendicular to the first line patterns, and second line patterns crossing the first line patterns and extending in such a manner as to overlap the first assist features. A first photomask may be formed including the first line patterns and the first assist features and a second photomask including the second line patterns. A first resist layer may be exposed through a first exposure process by using the first photomask, and a first resist pattern may be formed to open regions following the shape of the first line patterns. The first resist pattern may be frozen. A second resist layer may be formed to fill spaces between the opened regions of the first resist pattern. The second resist layer may be exposed through a second exposure process by using the second photomask, and a second resist pattern may be formed to open regions corresponding to the intersections between the first and second line patterns with the first resist pattern.

The first line patterns and the first assist features may be formed as light-transmitting regions of the first photomask.

The first assist features may be formed to have a CD as large as that of the first line patterns.

A dipole illuminator having dipole openings positioned in a direction perpendicular to the first line patterns may be used during the first exposure process such that images of the first assist features are not transferred onto the first resist layer by the first exposure process.

The first photomask may further include second assist features formed between the first line patterns and the first assist features and having a smaller CD than the first line patterns and the first assist features.

The second assist features may be formed in a line shape to extend in parallel to the first line patterns.

The first photomask may further include a first dummy line pattern formed between the first line patterns and the first assist features, extending in parallel to the first line patterns, and having a larger CD than the first line patterns.

The second photomask may include a second dummy line pattern formed outside the second line patterns in a direction perpendicular to the first dummy line pattern.

The second photomask may further include third assist features formed outside the second line patterns, having a smaller CD than the second line patterns such that images of the third assist features are not transferred during the second exposure process, and having a line shape to extend in parallel to the second line patterns.

The freezing of the first resist pattern may include applying a freezing agent to react with acid radicals that are generated in the first resist pattern by the first exposure process, and forming a protective layer on the surface of the first resist pattern through the reaction between the freezing agent and the acid radicals, the protective layer serving to protect the first resist patterns from the second resist layer. The first assist features may be formed as light-transmitting regions to provide exposure light which induces the acid radicals to be generated in corresponding portions of the first resist layer during the first exposure.

The method may further include introducing an underlying layer under the first resist layer, forming hole patterns by etching portions of the underlying layer exposed by the first and second resist patterns, and forming pillars to fill the hole patterns.

### BRIEF DESCRIPTION OF THE DRAWINGS

The above and other aspects, features and other advantages will be more clearly understood from the following detailed description taken in conjunction with the accompanying drawings, in which:

FIGS. 1 to 4 are diagrams illustrating photomasks and layouts used in a method for fabricating fine patterns in accordance with an embodiment of the present invention;

FIGS. 5 and 6 are diagrams illustrating modified illuminators used in the method for fabricating fine patterns in accordance with an embodiment of the present invention; and

FIGS. 7 to 19 are diagrams illustrating the method for fabricating fine patterns in accordance with an embodiment of the present invention.

### DESCRIPTION OF SPECIFIC EMBODIMENTS

Hereinafter, embodiments of the present invention will be described with reference to accompanying drawings. However, these various embodiments are for illustrative purposes only and are not intended to limit the scope of the invention.

A method for fabricating fine patterns in accordance with an embodiment of the present invention may be performed by an lithography-freezing-lithography-etching (LFLE) process in which a first resist pattern is formed by a first lithography process and then frozen, a second resist pattern crossing the first resist pattern is formed by a second lithography process, and an etching process is performed by using the first and second resist patterns as an etch mask. A photomask system is formed including a first photomask and a second photomask in which mask patterns are formed of a phase shift layer and/or light shielding layer. The photomask system is used to perform a first exposure process, a first development process, a freezing process, a second exposure process, and a second development process, whereby the first and second resist patterns intersect in a lattice shape. Such a fabrication method may overcome an exposure limit or pattern resolution limit in a single exposure process. Therefore, the patterns may be formed at a smaller size.

While a second exposure process and a second development process are performed after the second resist layer is applied, a process of freezing the first resist pattern may be performed to suppress the first resist pattern from being dissolved, worn, and deformed. The freezing process is to insolubilize the first resist pattern such that the first resist pattern is not dissolved in an alkali solution that may be used as a developing solution when the second resist pattern is developed. The freezing process may be performed by ultraviolet light irradiation, ion implantation, heat treatment, or protective layer formation.

In an embodiment of the present invention, the freezing process is performed by using a freezing agent. The freezing agent reacts with acid radicals (H⁺) that are generated when chemically amplified resist materials used as the resist layer react with exposure light, and forms a protective layer on the first resist pattern. A compound disclosed in US Patent Publication No. 2010/0183978 by Masahiro Yoshidome may be used as a freezing agent. The freezing agent may include a compound having an amino group such as —O—C—N— and/or an aromatic ring or a compound having a methyl group or a hydrolysis reactor such as the hydrogen atom. When the freezing agent reacts with acid radicals generated in the first resist pattern by the first exposure process, a crosslinking reaction with the resist materials forming the first resist pattern occurs to form a thin-film coating on the surface of the first resist pattern. The thin-film coating may serve as a protective layer that is not dissolved in a solvent used during the application of the second resist layer and a developing solution used during the second development process. Accordingly, it is possible to freeze the first resist pattern.

Although such a freezing process is performed, the first resist pattern may still dissolve to some extent when the second resist pattern is developed. In this case, an undesired pattern defect may occur in the first resist pattern. Such a pattern defect may be observed at a portion where first exposure light is insufficient when the first resist pattern is exposed by the first exposure process. For example, such a pattern defect may be observed at a portion of the first resist pattern that covers an edge region outside a cell region where the patterns are formed. In an embodiment of the present invention, in order to suppress such a pattern defect from occurring, the pattern layout of the first photomask used for forming the first resist pattern may be changed to induce a larger amount of first exposure light to be incident, within a limit in which a pattern image is not transferred and patterned in the region where such a pattern defect occurs.

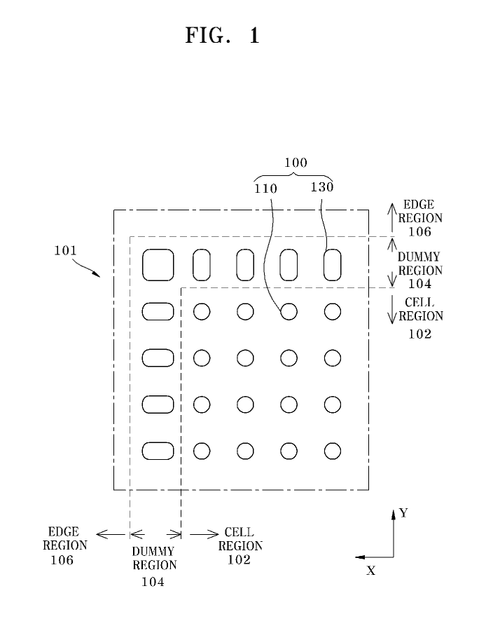

Referring to FIG. 1, there is shown a target layout 101 comprising cell patterns 110 in a cell region 102. The cell patterns may include hole patterns such as contact holes, for example. Outside the matrix arrangement of the cell patterns 110, dummy patterns 130 may be arranged in a dummy region 104 outside the cell region 102. The dummy patterns 130 may appear to be a continuation of the cell patterns 110. Actual patterns are not formed in an edge region 106 outside the dummy region 104.

When the outermost patterns among the cell patterns 110 are formed, the shape of the patterns may be deformed because the exposure environment or etching environment of the outermost patterns may be different from that of other patterns. In order to suppress such pattern deformation or pattern defect, the dummy patterns 130 are arranged in the dummy region 104, which is the boundary region between the edge region 106 and the cell region 102.

The dummy patterns 130 are formed to have a larger width or a larger critical dimension (CD) than the cell patterns 110, thereby reducing pattern deformation that may occur when the continuity of the pattern arrangement is cut off. That is, the dummy patterns 130 serve to provide a surrounding environment similar to that of the cell patterns 110 arranged inside. When cell patterns 110 adjacent to the dummy patterns 130 are photolithographed or etched, the cell patterns 110 adjacent to the dummy patterns 130 can be patterned in a more accurate shape by photolithography or etching without as much concern for pattern deformation. Such dummy patterns 130 may be designed as hole patterns having a larger CD than the cell patterns 110 or designed to have a rectangular hole shape while the cell patterns 110 are designed in a circular shape. The CD of the dummy patterns 130 may be set to be several times larger than that of the cell patterns 110.

The cell patterns 110 and the dummy patterns 130 are arranged for a target layout. Then, such a target layout is used to form photomasks through which pattern images are to be transferred onto a wafer during an exposure process. In this embodiment, it has been described that the cell patterns 110 include hole patterns. In addition to the hole patterns, the cell patterns 110 may be set to hard mask patterns or patterns for pillars or active regions.

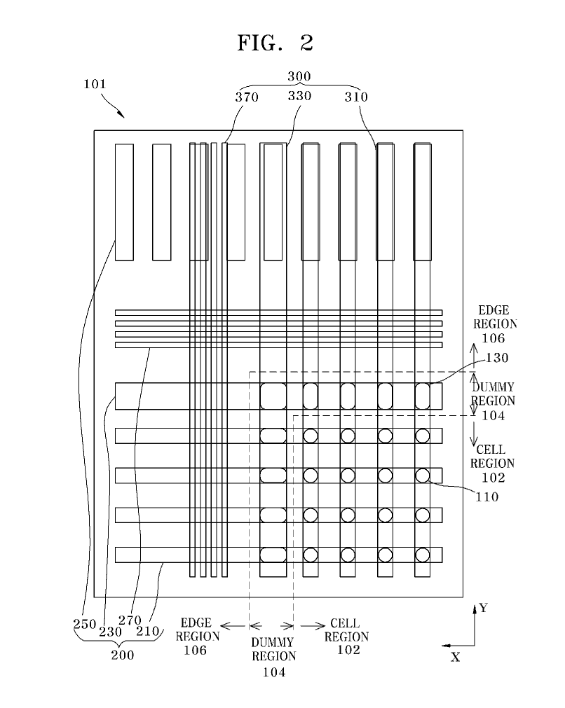

Referring to FIG. 2, the target layout 101 in which the cell patterns 110 and the dummy patterns 130 are arranged is used to form photomasks 200 and 300. First line patterns 210 and second line patterns 310 are arranged such that the cell patterns 110 are set at the intersections between the first line patterns 210 and the second line patterns 310. A first dummy pattern line 230 is arranged to have a larger CD than the first line patterns 210. For example, the CD for the first dummy pattern line 230 may be several times larger than the CD for the first line patter 210. Furthermore, a second dummy line pattern 330 is arranged to have a larger CD than the second line patterns 310, for example, where the CD may be several times larger. The first and second line patterns 210 and 310 may be set to have the same CD, and the first and second dummy line patterns 310 and 330 may be set to have the same CD. The first and second line patterns 210 and 310 and the first and second dummy line patterns 230 and 330 are set to light-transmitting regions through which exposure light is transmitted to transfer images onto a wafer.

The first and second line patterns 210 and 310 and the first and second dummy line patterns 230 and 330 may be in a line shape to extend from the cell region 102 and the dummy region 104 to the edge region 106. In general, an end portion of a line pattern tends to have a pattern CD that is unexpectedly decreased or increased in size by the exposure and development process. Therefore, the end portion is extended to the edge region 106 such that actual hole patterns are positioned in the middle of the line pattern where their size may not be affected by the exposure and development process.

First assist features 250 are arranged in the edge region 106 outside the first dummy line pattern 230. The first assist features 250 are generally in a direction perpendicular to the first line patterns 210. When the first line patterns 210 are set in a line shape extending in an X-axis direction, the first assist features 250 may be set in a line shape extending in a Y-axis direction perpendicular to the X-axis direction.

The first assist features 250 are set to transmit exposure light at such an intensity as not to transfer an image onto a resist layer on a wafer. That is, even though the first assist features 250 transmit the exposure light onto the wafer during an exposure process, patterns may not be formed on the wafer because insufficient light was transmitted. Furthermore, the first assist features 250 are set to light-transmitting regions that have CD allowing lower transmission of exposure light onto the wafer than a critical intensity needed to expose the resist layer.

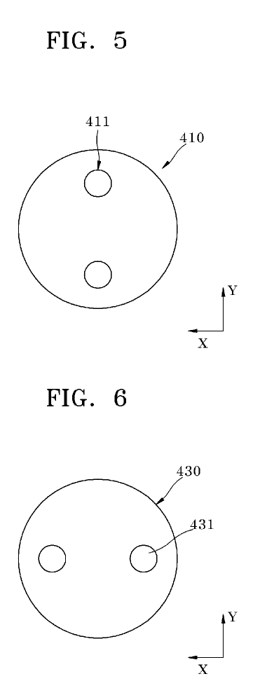

During a first exposure process for transferring the first line pattern 210, a Y-axis dipole illuminator 410 (FIG. 5) having dipole openings 411 (FIG. 5) in the Y-axis direction perpendicular to the X-axis direction is used to perform an exposure process in which a modified illuminator is used to increase the pattern resolution of the first line patterns 210. Therefore, the first assist features 250 are set to have a CD size such that patterns are not exposed and developed on the resist during the first exposure process in which the Y-axis dipole illuminator 410 is used.

Considering an asymmetric illuminator such as the Y-axis illuminator 410, the first assist features 250 may not transfer patterns onto the resist layer during the first exposure process, even though they have a CD corresponding to that of the first line patterns 210. Such first assist features 250 allow a larger amount of exposure light to be transmitted to portions of the resist layer on which patterns are not formed. Then, acid radicals that are to react with the freezing agent may be generated in the portions of the resist layer on which patterns are not formed. Accordingly, a protective layer may be formed by the freezing agent that is formed through a curing reaction with the first resist pattern. Accordingly, when the second resist layer is exposed by the second exposure process, it may be possible to effectively keep the first resist pattern from being deformed.

Referring to FIG. 2, second assist features 270 are inserted into the edge region between the first assist features 250 and the first dummy line pattern 230. The second assist features 270 serve to allow the shape of the first dummy line pattern 230 to be more accurately and precisely pattern-transferred onto the resist layer on the wafer. The second assist features 270 are extended parallel to the first line patterns 210 and are set to light-transmitting regions, and have a smaller CD than the first line patterns 210. For example, the CD of the second assist features 270 may be ½ to ¼ times the CD of the first line patterns 210.

The third assist features 370 are arranged in a line shape parallel to the second line patterns 310 to allow the shape of the second dummy line pattern 330 to be more accurately and precisely pattern-transferred onto the resist layer on the wafer. The third assist features 370 are set to light-transmitting regions, and have a smaller CD than the second line patterns 310. For example, the third assist features 370 may have a CD ½ to ¼ times smaller CD than the second line patterns 310. The second and third assist features 270 and 370 are assist features which are related to the size and margin of the patterns arranged in the cell region.

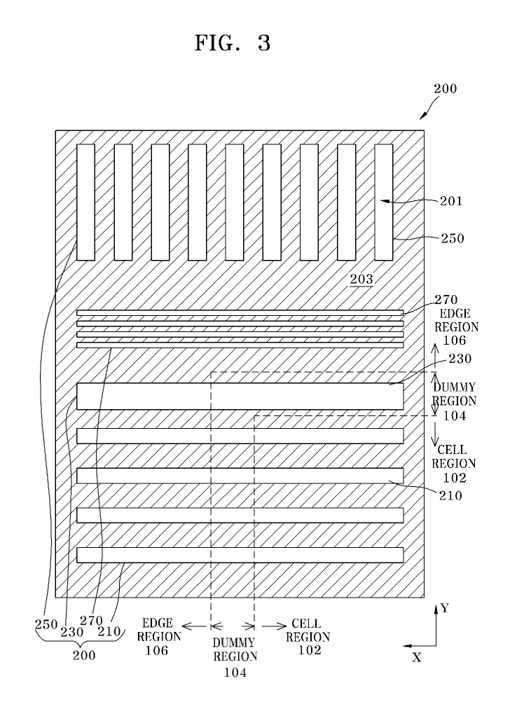

Referring to FIG. 3, the layout of the first photomask 200 including the first line patterns 210, the first dummy line pattern 230, the first assist features 250, and the second assist features 270 is extracted from the target layout 100 in which the cell patterns 110 and the dummy patterns 130 are arranged. The first mask pattern 203 to set the light-transmitting regions 201 is formed on a transparent substrate such as a quartz substrate, thereby enabling formation of the first photomask 200. The first mask pattern 203 may be formed of a phase shift layer such as MoSi alloy, and the light-transmitting regions 201 may be in transparent portions of the substrate. Accordingly, the first photomask 200 may be implemented as a phase shift mask (PSM). When the first mask pattern 203 is formed of a light shielding layer such as a Cr layer, the first photomask 200 may also be implemented as a PSM. Considering that the cell patterns 110 of FIG. 1 are to be formed as fine patterns, the first line patterns 210 and the first dummy line pattern 230 need to be pattern-transferred at a fine CD onto the first resist layer on the wafer. Therefore, the first photomask 200 may be implemented as a PSM that is capable of inducing a resolution improvement effect.

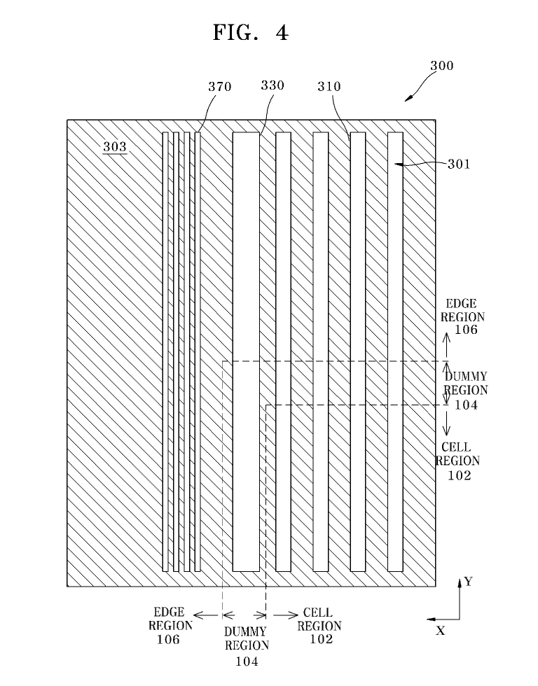

Referring to FIG. 4, the layout of the second photomask 300 including the second line patterns 310, the second dummy line pattern 330, and the third assist features 370 is extracted from the target layout 100 in which the cell patterns 110 and the dummy patterns 130 are arranged. The second mask pattern 303 to set light-transmitting regions 301 is formed on a transparent substrate such as a quartz substrate, thereby enabling formation of the second photomask 300. The second photomask 300 may be implemented as a PSM, similar to the first photomask 200.

A first lithography exposure process in the LFLE process using the first photomask 200 may be performed by using an asymmetric illuminator such as a Y-axis dipole illuminator 410 as illustrated in FIG. 5. The Y-axis dipole illuminator 410 may improve resolution by increasing the image contrast of the first line patterns 210 and the first dummy line pattern 230 extending in the X-axis direction. Furthermore, a second lithography exposure process in the LFLE process using the second photomask 300 may be performed by using an asymmetric illuminator such as the X-axis dipole illuminator 430 in which dipole openings 421 are arranged in the X-axis direction as illustrated in FIG. 6. The X-axis dipole illuminator 430 may improve resolution by increasing the image contrast of the second line patterns 310 and the second dummy line pattern 330 extending in the Y-axis direction.

The first and second photomasks 200 and 300 may be used to perform the first and second lithography exposure processes.

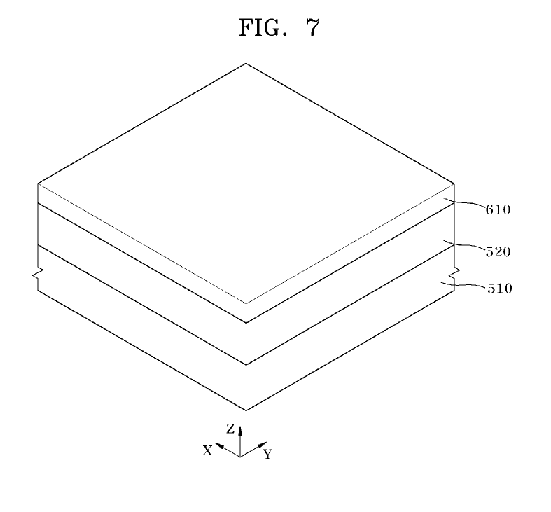

Referring to FIG. 7, a wafer 510 is introduced as an underlying layer, and an insulation layer 520 is introduced as an etching target layer on the wafer 510. The insulation layer 520 is coated with a first resist layer 610. When the exposure process is performed by using, for example, an ArF lithography system, the first resist layer 610 may be formed of ArF exposure resist that is an amplified resist material.

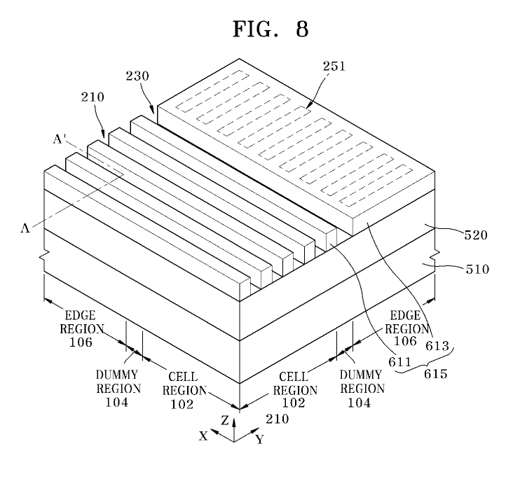

Referring to FIG. 8, the first resist layer 610 is exposed and developed through a first exposure process and a first development process by using the first photomask 200, thereby forming the first resist pattern 615 that opens regions of the insulation layer 520 corresponding to the first line patterns 210 and the first dummy line pattern 230. The first exposure process may then be performed by using an ArF exposure system using the Y-axis dipole illuminator of FIG. 5 or an immersion exposure system.

The first resist pattern 615 includes a first-resist first pattern portion 611 and a first-resist second pattern portion 613 formed in the cell region 102 and the dummy region 104, respectively. The first-resist first pattern portion 611 has openings 210 and 230 that expose the regions of the insulation layer 520 corresponding to the first line patterns 210 and the first dummy line pattern 230. The first-resist second pattern portion 613 may cover a portion of the edge region 106. Light irradiation portions 251 of the first-resist second pattern portion 613 may be irradiated with exposure light via the first assist features 250.

Since the first assist features 250 extend in a direction coinciding with the positions of dipole openings 411 of the Y-axis dipole illuminator 410 of FIG. 5, the pattern resolving power with respect to the first assist features 250 is deceased, and thus the pattern images of the first assist features 250 are not formed in the first-resist second pattern portion 613. Accordingly, a considerable amount of exposure light may be allowed to be incident on the first-resist second pattern portion 613. Specifically, a pattern image is formed in the first-resist first pattern portion 611, and a large amount of light approaching the amount of incident exposure light is incident on the first-resist second pattern portion 613. Therefore, since the first resist is formed of an amplified resist material, a considerable amount of acid radicals may be generated in the light irradiation portions 251 of the first-resist second pattern portion 613 by the irradiation of exposure light.

The incidence of the considerable amount of light on the first-resist second pattern portion 613 during the first exposure process may be proved by a simulation. The simulated results are obtained by simulating the first exposure process using the first photomask 200 and measuring the light intensity at the first assist features 250. Considering the light intensity distribution of the simulated result, the amount of light needed on the first-resist first pattern portion 611 to form actual patterns such as the first dummy line pattern 230 may be a light intensity of 0.5 at a light intensity scale. The light intensity scale is a ratio of the exposure light intensity to the measured light intensity. The amount of light incident on the first-resist second pattern portion 613 by the first assist features 250 approaches a light intensity of about 0.278, which shows that a considerable amount of light is incident. Accordingly, a considerable amount of acid radicals may be generated in the first-resist second pattern portion 613.

On the other hand, when only the second assist features 270 are expanded and arranged in the portions where the first assist features 250 are arranged, instead of the first assist features 250, it shows an opposite simulation result. The opposite simulation results are obtained by simulating the first exposure process and measuring the light intensity at the second assist features 270. Considering the simulation result, the amount of light incident on the first-resist second pattern portion 613 by the second assist features 270 is measured to a very low intensity of about 0.0556. Such a light intensity does not generate acid radicals in the first-resist second pattern portion 613.

Considering the simulation results, the first assist features 250 in accordance with an embodiment of the present invention are not formed as patterns in the first resist pattern 615 of FIG. 8, but to allow a considerable amount of light or a considerable intensity of light to be incident on the first-resist second pattern portion 613. Furthermore, due to the introduction of the first assist features 250, a considerable amount of exposure light is also incident on the first-resist second pattern portion 613 where actual patterns are not formed, thereby generating acid radicals.

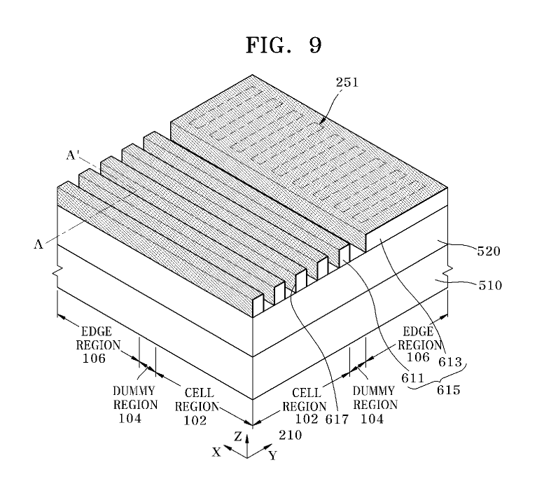

Referring to FIG. 9, the first resist pattern 615 is maintained in a state in which the development process is performed, and a post exposure bake process generally performed after the first exposure process and the first development process are omitted. A freezing process is performed on the first resist pattern 615. To substantially prevent the first resist pattern 615 from being dissolved and deformed during a second resist coating process, a second exposure process, and a second development process, the process of freezing first resist pattern 615 is performed. Such a freezing process may be performed by ultraviolet light irradiation, ion implantation, heat treatment, or protective layer formation. In this embodiment of the present invention, the freezing process is performed by using a freezing agent. The freezing agent reacts with acid radicals (H⁺) that are generated when chemically amplified resist materials react with exposure light, and hardens the surface of the first resist pattern to form a protective layer on the first resist pattern.

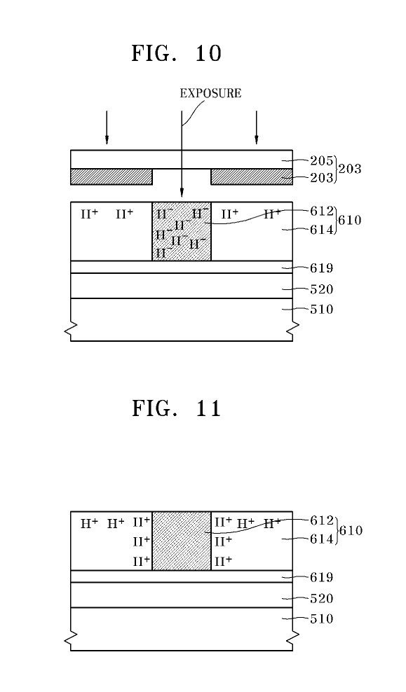

FIGS. 10 to 15 illustrate the freezing process in which the protective layer 617 is formed by the freezing agent. Referring to FIG. 10, a first resist layer 610 is applied on the wafer insulation layer 520, a soft bake process is performed, and the first exposure process is then performed by using the first photomask 200. At the interface between the first resist layer 610 and the insulation layer 520, a bottom anti-reflection coating (BARC) 619 may be introduced. When exposure light is incident with a pattern image on the first resist layer 610 through the first photomask 200 having a first mask 203 formed on the transparent substrate 205, a photoacid generator (PAG) absorbs light at a portion 612 on which the exposure light is irradiated, thereby generating a large amount of acid radicals. In the other portion 614 on which the exposure light is not irradiated, a slight amount of acid radicals may be generated by diffused light.

Referring to FIG. 11, a post exposure bake (PEB) process is performed to generate acids. The acids generated by the PEB process serve as a catalyst to sequentially generate hydroxyl radicals at a side ring of resin forming the first resist layer 610. Referring to FIG. 12, such hydroxyl radicals react with an alkali developing solution, and the portion 612 on which the exposure light is irradiated is dissolved in the developing solution, thereby forming the first resist pattern 615.

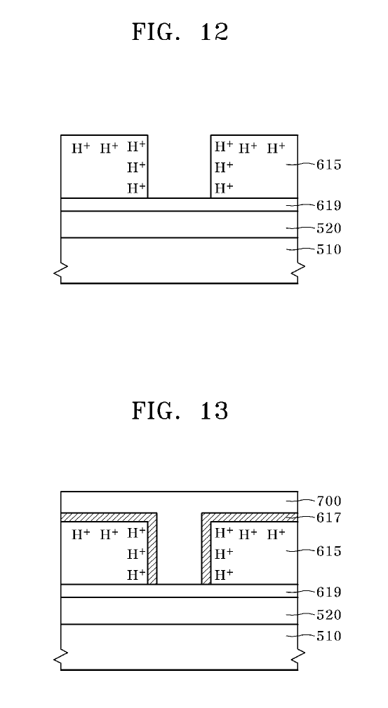

Referring to FIG. 13, the freezing agent 700 is applied, and a soft bake process is performed. The soft bake process is performed at temperature of 130 to 180° C. for one or two minutes, for example. Then, the freezing agent 700 and the surface of the first resist pattern 615 are cross-linked to form a protective layer 617. At this time, the surface reaction between the freezing agent 700 and the first resist pattern 615 may be performed only when acid radicals exist. In this embodiment of the present invention, a considerable amount of exposure light may also be incident on the light irradiation portions 251 of the first-resist second pattern portion 613, as illustrated in FIG. 8. Therefore, a considerable amount of acid radicals may be generated in the first-resist second pattern portion 613 on which diffused exposure light is hardly incident. Accordingly, a considerable surface reaction may take place between the freezing agent 700 and the first resist pattern 615. As a result, it is possible to effectively prevent the protective layer 617 from becoming vulnerable in the first-resist second pattern portion 613 due to the lack of acid radicals.

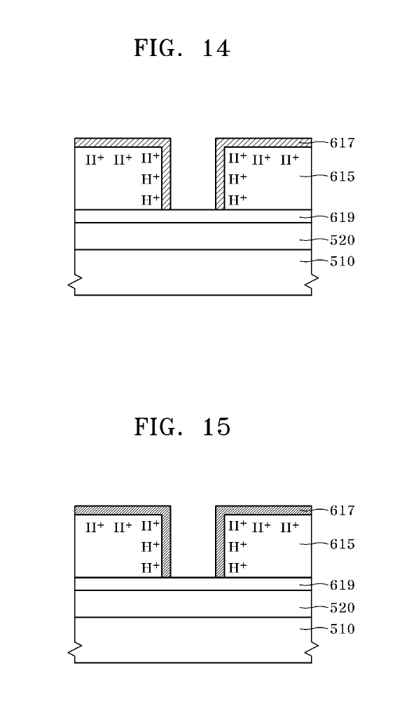

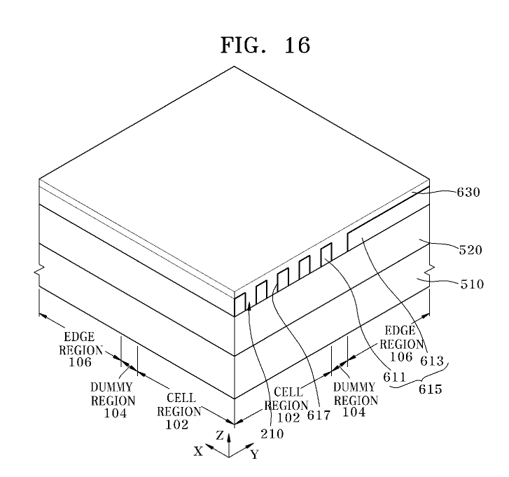

Referring to FIG. 14, the unreacted freezing agent 700 is developed and removed. Referring to FIG. 15, a freeze bake process is performed to cure the protective layer 617. Through such a freezing process, the protective layer 617 if formed for protecting the first resist pattern 615.

Referring to FIG. 16, the first resist pattern 615 is frozen by the protective layer 617, and a second resist layer 630 is then applied on the first resist pattern 615. The second resist layer 630 may be formed of the same resist material as or a different resist material from the first resist pattern 615.

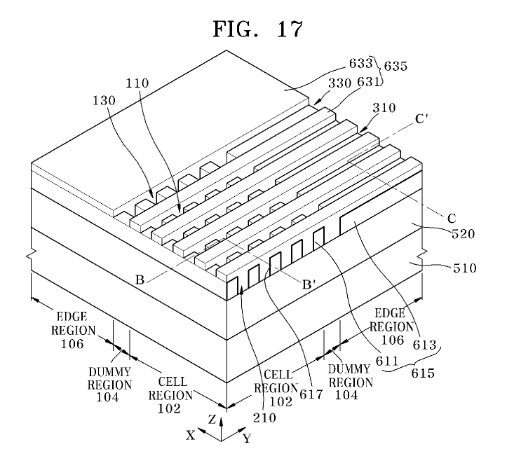

Referring to FIG. 17, the second photomask 300 is used to expose and develop the second resist layer 630 through the second exposure process and the second development process, thereby forming a second resist pattern 635 with cell patterns 110 corresponding to the intersections between the first and second line patterns 210 and 310. There may also be formed dummy patterns 130 corresponding to the intersections between the first dummy line pattern 230 and the second line patterns 310 and corresponding to the intersections between the second dummy line pattern 230 and the first line patterns 210.

The second exposure process may be performed using an ArF exposure system or immersion exposure system using the X-axis dipole illuminator 430 of FIG. 6. The second resist pattern 635 includes a second-resist first pattern portion 631 and a second-resist second pattern portion 633 formed in the cell region 102 and the dummy region 104, respectively. The second-resist first pattern portion 631 has openings 310 and 330 which open portions of the insulation layer 520 corresponding to the second line patterns 310 and the second dummy line pattern 330. The second-resist second pattern portion 633 may cover a portion of the edge region 106.

The second-resist second pattern portion 631 is superimposed on the first-resist second pattern portion 613, and the light-transmitting regions such as the first-resist second pattern portion 613, the second line patterns 310, and the second dummy line pattern 330 are positioned. Therefore, during the second exposure process, the exposure light is incident at an intensity that patterns are transferred on to the first-resist second pattern portion 613. The first-resist second pattern portion 613 corresponds to a portion where a considerable amount of acids was generated by light having transmitted the first assist features 250 during the first exposure process, and such acids have already been consumed through the reaction with the freezing agent during the freezing process for forming the protective layer 617.

The protective layer 617 is more closely and precisely formed by the generated acids, and the first-resist second pattern portion 613 is hardened while the protective layer 617 is formed. Therefore, the occurrence of defects in patterns exposed by the second exposure process and developed by the second development process may be effectively reduced. Furthermore, since a larger amount of acids may be generated and react with the freezing agent to strengthen the protective layer 617, the first-resist second pattern portion 613 may be further hardened. Accordingly, while suppressing pattern defects such as undesired loss or patterning of the first-resist second pattern portion 613, fine patterns may be formed through the LFLE process. Furthermore, a process of intentionally hardening and fixing the first-resist second pattern portion 613, that is, a process of exposing and curing the first-resist second pattern portion 613 by using a separate third photomask that opens only the first-resist second pattern portion 613 is not required. Therefore, the number of photomasks may be reduced, which makes it possible to realize process improvement.

The first and second resist patterns 615 and 635 intersect to form a lattice shape, and the regions corresponding to the intersections between the first and second line patterns 210 and 310 correspond to the cell patterns 110 of FIG. 1. The regions corresponding to the intersections between the first dummy line pattern 230 and the second line patterns 310 are formed as patterns corresponding to the dummy patterns 130 of FIG. 1.

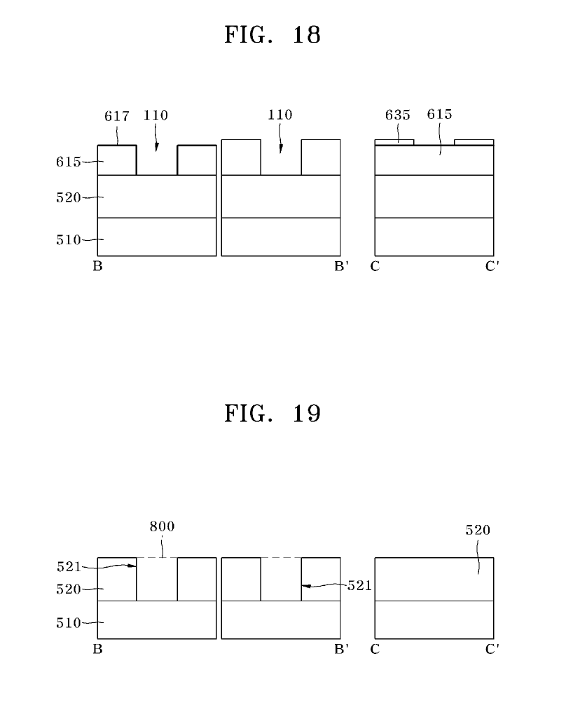

FIGS. 18 and 19 are cross-sectional views taken along lines B-B′ and C-C′ of FIG. 17. Referring to FIG. 18, portions of the insulation layer 520 are exposed through hole patterns, which are the cell patterns 110 of the first and second resist patterns 615 and 635. In the edge region in the X-axis direction, the first resist pattern 615 is positioned to cover and shield the insulation layer 520. In the edge region in the Y-axis direction, the second resist pattern 635 is positioned to cover and shield the insulation layer 520. Referring to FIG. 19, the portions of the insulation layer 520 exposed by the first and second resist patterns 615 and 635 are selectively etched to form through-holes which are cell patterns 521 passing through the insulation layer 520. Dummy patterns may also be formed in the same manner. The insulation layer 520 may be used as a hard mask that is to be used as an etch mask during a subsequent etching process or patterning process, or may be used as a mold for applying a pillar shape to a layer filling the cell patterns 521.

For example, the layer filling the cell patterns 521 may be deposited, and planarized, by a chemical mechanical polishing (CMP) process to form pillars 800. When the pillars 800 are formed as an insulation layer for a hard mask, the insulation layer 520 is selectively removed to expose the pillars 800 as the hard mask. The pillars 800 are used to selectively etch the wafer 510 and form trenches for a field region which sets the cell active. Furthermore, when the pillars 800 are formed of a conductive polysilicon layer or metal layer such as tungsten (W) or titanium nitride (TiN), the pillars 800 may be applied as lower electrodes of the phase change random access memory. A phase change material such as calconite is deposited on the pillars 800, and upper electrodes are formed on the pillars 800 having the phase change material deposited thereon, thereby forming the phase change memory device.

In accordance with an embodiment of the present invention, when the fine patterns are fabricated by using the LFLE process, it is possible to the first resist pattern from being deformed or developed during the process of forming the second resist pattern.

Various embodiments of the present invention have been disclosed above for illustrative purposes. Those skilled in the art will appreciate that various modifications, additions, and substitutions are possible, without departing from the scope and spirit of the invention as disclosed in the accompanying claims.

What is claimed is:

1. A method for fabricating fine patterns, comprising:
forming a first photomask including first line patterns and first assist features positioned outside the first line patterns, and having a line shape in a direction perpendicular to the first line patterns;
forming a second photomask including second line patterns extending to a portion corresponding to the first assist features in a direction perpendicular to the first line patterns;
exposing a first resist layer through a first exposure process by using the first photomask, and forming a first resist pattern to open regions following the shape of the first line patterns;
freezing the first resist pattern;
forming a second resist layer to fill the opened regions of the first resist pattern; and
exposing the second resist layer through a second exposure process by using the second photomask, and forming a second resist pattern to open regions corresponding to the intersections between the first and second line patterns, with the first resist pattern.

2. The method of claim 1, wherein the first line patterns and the first assist features are formed as light-transmitting regions of the first photomask.

3. The method of claim 1, wherein the first assist features are formed to have a CD as large as that of the first line patterns.

4. The method of claim 3, wherein a dipole illuminator having dipole openings positioned in a direction perpendicular to the first line patterns is used during the first exposure process such that images of the first assist features are not transferred onto the first resist layer by the first exposure process.

5. The method of claim 1, wherein the first photomask further includes second assist features formed between the first line patterns and the first assist features and having a smaller CD than the first line patterns and the first assist features.

6. The method of claim 5, wherein the second assist features are formed in a line shape to extend in parallel to the first line patterns.

7. The method of claim 1, wherein the first photomask further includes a first dummy line pattern formed between the first line patterns and the first assist features, extending in parallel to the first line patterns, and having a larger CD than the first line patterns.

8. The method of claim 7, wherein the second photomask includes a second dummy line pattern formed outside the second line patterns in a direction perpendicular to the first dummy line pattern.

9. The method of claim 1, wherein the second photomask further includes third assist features formed outside the second line patterns, having a smaller CD than the second line patterns such that images of the third assist features are not transferred during the second exposure process, and having a line shape to extend in parallel to the second line patterns.

10. The method of claim 1, wherein the freezing of the first resist pattern comprises:
applying a freezing agent to react with acid radicals that are generated in the first resist pattern by the first exposure process; and
forming a protective layer on the surface of the first resist pattern through the reaction between the freezing agent and the acid radicals, the protective layer serving to protect the first resist patterns from the second resist layer,
wherein the first assist features are formed as light-transmitting regions to allow transmission of exposure light that induces the acid radicals to be generated in corresponding portions of the first resist layer during the first exposure.

11. The method of claim 1, further comprising:
introducing an underlying layer under the first resist layer;
forming hole patterns by etching portions of the underlying layer exposed by the first and second resist patterns; and
forming pillars to fill the hole patterns.

12. A method for fabricating fine patterns, comprising:
defining a cell region in which cell patterns are to be formed and an edge region outside the cell region on a wafer;
forming a first photomask including first line patterns extending in an X-axis direction from the cell region to the edge region, and first assist features positioned in the edge region outside the first line patterns and having a line shape in a Y-axis direction perpendicular to the X-axis direction;
forming a second photomask including second line patterns extending in the Y-axis direction from the cell region to the edge region;
exposing the first resist layer through a first exposure process by using the first photomask, and forming a first resist pattern to open regions following the shape of the first line patterns;
freezing the first resist pattern;
forming a second resist layer to fill the opened regions of the first resist pattern; and
exposing the second resist layer through a second exposure process by using the second photomask, and forming a second resist pattern that opens regions corresponding to the intersections between the first and second line patterns as the cell patterns, with the first resist pattern.

13. The method of claim 12, wherein the first assist features are formed to have a CD as large as that of the first line patterns.

14. The method of claim 12, wherein the first photomask includes second assist features formed between the first line patterns and the first assist features, having a smaller CD than the first line patterns and the first assist features, and having a line shape parallel to the first line patterns.

15. The method of claim 12, wherein the first photomask further includes a first dummy line pattern formed between the first line patterns and the first assist features, extending in parallel to the first line patterns, and having a larger CD than the first line patterns.

16. The method of claim 12, wherein the freezing of the first resist pattern comprises:
applying a freezing agent to react with acid radicals generated in the first resist pattern by the first exposure; and
forming a protective layer on the surface of the first resist pattern through the reaction between the freezing agent and the acid radicals, the protective layer serving to protect the first resist pattern from the second resist layer,
wherein the first assist features are formed as light-transmitting regions to provide exposure light which induces the acid radicals to be generated in corresponding portions of the first resist layer during the first exposure process.

17. The method of claim 12, further comprising:
introducing an underlying layer under the first resist layer;
forming hole patterns by etching portions of the underlying layer exposed by the cell patterns; and
forming pillars to fill the hole patterns.

18. A method for fabricating fine patterns, comprising:
obtaining a photomask layout including first line patterns, first assist features formed outside the first line patterns and having a line shape in a direction perpendicular to the first line patterns, and second line patterns crossing the first line patterns and extending in such a manner as to overlap the first assist features;
forming a first photomask including the first line patterns and the first assist features and a second photomask including the second line patterns;
exposing a first resist layer through a first exposure process by using the first photomask, and forming a first resist pattern to open regions following the shape of the first line patterns;
freezing the first resist pattern;
forming a second resist layer to fill spaces between the opened regions of the first resist pattern; and
exposing the second resist layer through a second exposure process by using the second photomask, and forming a second resist pattern to open regions corresponding to the intersections between the first and second line patterns, with the first resist pattern.

19. The method of claim 18, wherein the first photomask includes second assist features formed between the first line patterns and the first assist features, having a smaller CD than the first line patterns and the first assist features, and having a line shape in parallel to the first line patterns.

20. The method of claim 18, wherein the first photomask further includes a first dummy line pattern formed between the first line patterns and the first assist features, extending in parallel to the first line patterns, and having a larger CD than the first line patterns.
